(19) United States
(12) Patent Application Publication
(10) Pub. No.: US 2009/0014061 A1
(43) Pub. Date: Jan. 15, 2009

(54) GaInNAsSb solar cells grown by molecular beam epitaxy

(75) Inventors: James S. Harris, JR., Stanford, CA (US); Homan B. Yuen, Sunnyvale, CA (US); Seth R. Bank, Austin, TX (US); Mark A. Wistey, Santa Barbara, CA (US); David B. Jackrel, Pacifica, CA (US)

Correspondence Address: Stanford University, 1705 EL CAMINO REAL, PALO ALTO, CA, 94306, US

(73) Assignee: The Board of Trustees of the Leland Stanford Junior University, Palo Alto, CA (US)

(21) Appl. No.: 12/217,818

(22) Filed: Jul. 8, 2008

Related U.S. Application Data
(60) Provisional application No. 60/959,043, filed on Jul. 10, 2007.

(51) Int. Cl. H01L 31/00

(52) U.S. Cl. 136/255

(57) ABSTRACT

A high efficiency triple-junction solar cell and method of manufacture therefor is provided wherein junctions are formed between different types of III-V semiconductor alloy materials, one alloy of which contains a combination of an effective amount of antimony (Sb) with gallium (Ga), indium (In), nitrogen (N, the nitride component) and arsenic (As) to form the dilute nitride semiconductor layer GaInNAsSb which has particularly favorable characteristics in a solar cell. In particular, the bandgap and lattice matching promote efficient solar energy conversion.

### CROSS-REFERENCES TO RELATED APPLICATIONS

This application claims benefit under 35 U.S.C. § 119(e) of Provisional Patent Application 60/959,043 filed Jul. 10, 2007 entitled Improved Carrier Lifetime and Mobility in Dilute Nitrides Grown by MBE Via Ion Count Reduction, the content of which is incorporated herein for all purposes.

### STATEMENT AS TO RIGHTS TO INVENTIONS MADE UNDER FEDERALLY SPONSORED RESEARCH OR DEVELOPMENT

This material is based on work supported by the NSF under Grants No. 9900793 and No. 0140297, with imaging and measurements carried out by NREL under Contract No. DE-AC36-99GO10337 with the U.S. Department of Energy. The subject matter herein described is subject to a government license in connection with Leland Stanford Junior University.

### REFERENCE TO A “SEQUENCE LISTING,” A TABLE, OR A COMPUTER PROGRAM LISTING APPENDIX SUBMITTED ON A COMPACT DISK

Not Applicable

### BACKGROUND OF THE INVENTION

This invention relates to solar cell technology and in particular to high efficiency multi-junction solar cells comprising III-V semiconductor alloy materials.

It is known that nitride-containing III-V semiconductor alloys can be used to form electron-generating junctions and further that a class called dilute nitride films can be lattice-matched to gallium arsenide or germanium while producing a roughly 1 eV band gap. To date most dilute nitride solar cells have been plagued with poor efficiency, due presumably to short diffusion lengths. Moreover, work done by other researchers resulted in the conclusion that certain materials, specifically antimony, have unconditionally deleterious effects on solar conversion efficiency such that the presence of antimony in alloy is to be minimized. Ptak et al., “Effects of Temperature, Nitrogen Ions and Antimony on Wide Depletion Width GaInNAs,” J. Vac. Sci. Tech. B25(3), page 955, May/June 2007 (published May 31, 2007).

The current world record efficiency solar cell is a triple-junction cell, which is composed of the three layers GaInP/InGaAs/Ge. An efficiency of 40.7% measured at 240 suns concentration has been reported by R. R. King et al., in the journal Applied Physics Letters on May 4, 2007. This world record device is metamorphic (and consequently contains a high concentration of deleterious defects introduced by growth of metamorphic layers), but the best lattice-matched GaInP/InGaAs/Ge solar cell has an efficiency that is very similar, namely, 40.1% at 135 suns concentration, as reported in the same article. The InGaAs middle layer of the lattice-matched cell has a band gap of 1.4 eV. However, monolithic multi-junction cell efficiencies could benefit from materials with band gaps between 0.95 and 1.3 eV (depending on the use of three or four junctions and the concentration ratio), according to M. A. Green, Third Generation Photovoltaics: Advanced Solar Energy Conversion, Springer Publishing, Berlin, Germany. This explains why slightly higher efficiencies are possible using metamorphic structures. The dilute nitrides, which include GaInNAs and GaInNAsSb, are the only known material systems that have band gaps between 0.9 and 1.3 eV and can be lattice-matched to germanium or GaAs. These materials can raise device efficiency without the need for metamorphic structures, which inherently contain many defects in the graded region, are generally thicker due to the graded buffer layer, and are more difficult to manufacture than lattice-matched structures. It is also possible to create triple-junction cells using a dilute nitride subcell instead of a germanium subcell. Such a cell has an ideal efficiency of 44.5% under the 500-sun low-AOD (aerosol optical depth) solar spectrum, which is higher than the ideal efficiency of the current GaInP/GaAs/Ge cells, which is 40%, according to Friedman et al., Conference Record of the Twenty-ninth IEEE Photovoltaic Specialists Conference, New Orleans, La., 19-24 May 2002, pp. 856-859. The elimination of the thick germanium subcell also enables other applications, such as very light or flexible solar cells, and cogeneration using the photons with energy below 0.9 eV.

GaInNAs solar cells have been created with nearly 100% quantum efficiency, but they all had band gaps larger than 1.15 eV, according to Ptak, Friedman, and others, Journal of Applied Physics, 98.094501 (2005). However, narrow band gap GaInNAs solar cells with band gaps at or below 1.0 eV are reported (by Friedman et al. in Conference Record of the Thirty-first IEEE Photovoltaic Specialists Conference, Lake Buena Vista, Fla., 3-7 Jan. 2005, pp. 691-694) to be plagued with poor performance due to short diffusion lengths coupled with narrow depletion widths. This can be related to the increased nitrogen content required to achieve the lower band gap materials.

In highly strained GaInNAs films, (i.e., poorly lattice matched structures), such as quantum wells used in laser structures, the material quality and laser performance can be greatly improved through the introduction of antimony during molecular beam epitaxy (MBE) growth. The exact role of antimony during dilute nitride growth is not conclusively known.

Biased deflection plates installed in front of the rf-plasma nitrogen sources used to produce active nitrogen in MBE have been used to improve the material quality in thin, highly strained GaInNAs films as well. A moderate dc bias (−40 V) applied across the plates creates an electric field which deflects the high-energy charged species in the plasma away from the growing film surface. Strained GaInNAs quantum wells have been grown using deflection plates that displayed higher photoluminescence intensity than similar films grown without deflection plate bias, which indicates a reduction in the nonradiative recombination associated with ion damage induced point defects. The lasers produced from these quantum well structures also displayed lower threshold currents and higher lasing efficiencies.

What is needed is a structure and a technique that achieves a high efficiency solar cell and overcomes the problems of a narrow band gap and achieves nearly lattice-matched structures important in a multi-junction solar cell that takes advantage of the properties of dilute nitride films.

### SUMMARY OF THE INVENTION

According to the invention, a high efficiency triple-junction solar cell and method of manufacture therefor is provided wherein junctions are formed between different types of III-V semiconductor alloy materials formed in subcells, one alloy of which contains a combination of an effective amount of antimony (Sb) with gallium (Ga), indium (In), nitrogen (N, the nitride component) and arsenic (As) to form the dilute nitride semiconductor layer or subcell GaInNAsSb which has particularly favorable characteristics in a solar cell. An effective amount of antimony has been determined to be between about 2% and 6%. In particular, the bandgap and lattice matching promote efficient solar energy conversion.

In one aspect of the invention, a method of manufacturing using molecular beam epitaxy is provided, wherein voltage-biased deflection plates that are disposed at the front of a nitrogen plasma cell in an MBE system can reduce the number of ions impinging on the dilute nitride epilayer as it is being grown. Other design parameters that can be selected to reduce the ion flux at the epilayer include: the number and/or size of holes at the front aperture of the plasma cell, the location and/or pattern of these holes, RF power delivered to the source and gas pressure in the source. Since ions impinging on the epilayer being grown can damage the epilayer and introduce defects, it is significantly advantageous to reduce the incident ion flux during growth.

In a second aspect of the invention, compositional and phase segregation are reduced, and native defect concentration is also reduced in dilute nitrides, thereby improving carrier lifetime and diffusion length. The resulting dilute nitrides can have improved surface quality and can provide increased efficiency in solar cells. The antimony (Sb) is believed to serve as a surfactant, and a low percentage (<10%) constituent can improve the quality of dilute nitrides. Specifically, addition of antimony (Sb) reduces the propensity of indium (In) and nitrogen (N) to segregate during growth and also inhibits 3-D growth. As a result, a higher temperature growth window is made available providing fewer native defects. The resulting grown material has superior transport and p-n junction properties.

In a third aspect of the invention, an epitaxially grown dilute nitride antimonide layer is lattice matched to a GaAs or Ge substrate and has a bandgap of 0.9 eV to 1.1 eV. Such a layer can be the ˜1 eV junction of a high efficiency multi-junction solar cell. More specifically, GaNAsSb or GaInNAsSb can be grown with a set of compositions that provide a bandgap of 0.9 eV to 1.1 eV together with lattice matching to GaAs or Ge. This layer can be part of a multi-junction solar cell, absorbing light having energy ˜1 eV and greater. This material composition for the 1 eV layer can provide reduced defect density compared to conventional approaches based on an InGaAs 1 eV layer. Reduction of defect density can increase cell efficiency.

The invention will be better understood by reference to the following detailed description in connection with the accompanying drawings.

### BRIEF DESCRIPTION OF THE DRAWINGS

FIG. 1A is a schematic cross section of a specific materials structure for a dilute nitride film layer according to the invention.

FIG. 1B is a schematic cross section of a multi-layer solar cell incorporating the invention.

FIG. 2 is a graph showing plots of the internal quantum efficiency (IQE) of representative devices for comparison

FIG. 3 is a graph showing plots of current-voltage responses devices for comparison.

FIG. 4 is a graph showing plots of the open-circuit voltage of three devices versus band gap energy of the alloy material.

FIG. 5 is a graph showing the dark current-voltage character of three types of devices for comparison.

FIG. 6 is a graph showing background doping density vs. depletion width of three devices for comparison.

FIG. 7 is a plot of depletion level spectroscopy of three devices for comparison.

FIG. 8 is a graph showing the lattice constants of three types of dilute nitride films for comparison.

### DETAILED DESCRIPTION OF THE INVENTION

Two techniques have been explored that have been aimed at improving the quality of thicker narrow band gap, nearly lattice-matched III-V type dilute nitride films in solar cells grown by molecular beam epitaxy (MBE), namely the utilization of biased deflection plates installed in front of the nitrogen plasma source, and the introduction of antimony to the growth process. The experimental results indicate that antimony-containing nitride films above certain concentrations actually improved performance of solar cells, in contrast to prior art teachings that the presence of antimony was deleterious to the achievement of desired characteristics useful in a solar cell.

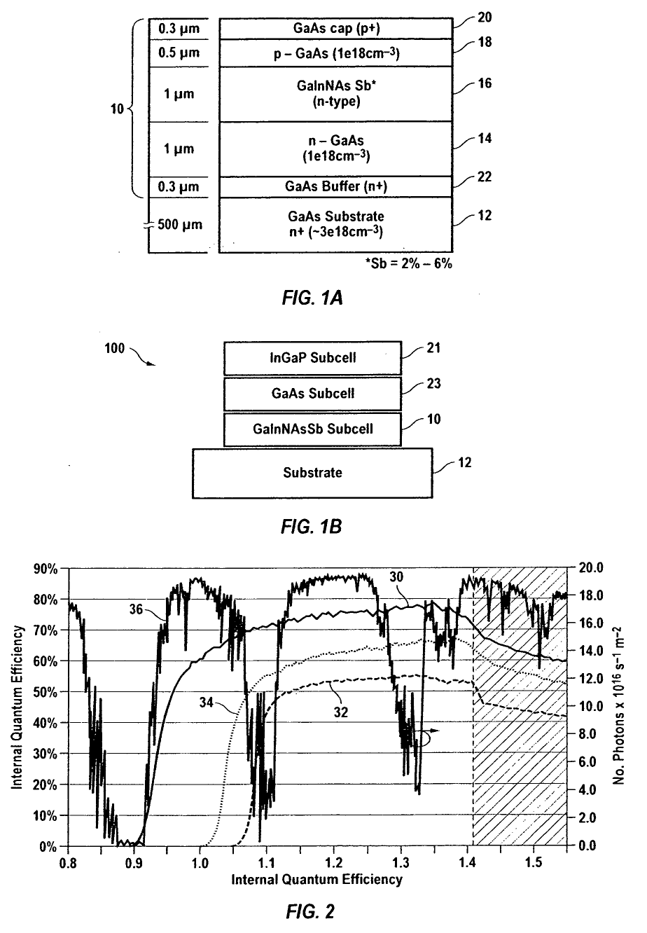

According to the invention and in reference to FIGS. 1A and 1B, a material system 10, herein a layer, which contains a dilute nitride film (FIG. 1A), that specifically contains antimony in the nitride film, namely, GaInNAsSb 16 with approximately 2% to 6% antimony (“Sb”), can be grown on a substrate 12 that is suitable for growing III-V materials (specifically a gallium arsenide (GaAs substrate 12) using MBE techniques with biased deflection plates, and can be fabricated into a triple-junction solar cell 100 (FIG. 1B illustrating one possible embodiment). One of the layers, such as the topmost layer 21 of the solar cell 100 may be an alloy of gallium, indium and phosphorous, and in an alternative with an additional component of phosphorous. A third layer 23 may be gallium arsenide (GaAs). It is understood that these layers may be formed with various auxiliary layers and growths, as hereinafter explained in connection with the material system forming the layer 10 of particular interest in this invention. In addition, an alternate substrate 12 is germanium.

As part of an experimental verification, for comparison, various forms of dilute nitride GaInNAs films were grown, i.e., with and without biased deflection plates and without the antimony, and comparable-structure solar cells were fabricated from these materials. Testing revealed that the fabrication method using biased deflection plates improved every aspect of GaInNAs solar cell performance. (It is speculated that the use of deflection plates reduced the dark current density in the GaInNAs films, which would partially explain the improvement in solar cell characteristics. However, the presence of a parasitic junction in the GaInNAs devices makes it difficult to determine all of the effects of the deflection plates with certainty.) The materials grown using deflection plate bias had no observed hole traps near the middle of the band gap. According to the invention, the use of effective amounts of antimony in the GaInNAsSb layer 10 of a three-junction solar cell device 100 provides improved collection efficiency even though degraded open-circuit voltage and fill factor are evident. Nevertheless, the GaInNAsSb-based solar cell device 100 is the first dilute nitride solar cell type to generate enough short-circuit current to current-match with the upper subcells 23, 21 (FIG. 1B) in any known design for a three-junction solar cell. The open-circuit voltage of GaInNAsSb solar cells 100 according to the invention is also higher than that of germanium (Ge) cells at 1-sun illumination. The improved collection efficiency of the antimonide devices is believed to be due largely to wide depletion widths created by low background doping densities. However, the antimony-containing film 16 shows substantially increased dark current compared to the GaInNAs (DP) devices, but much of this increase is due to the smaller band gap of the antimonide material and is thus unavoidable. The GaInNAsSb material is the only film that exhibits significant film relaxation, evidently due to a larger lattice constant mismatch between the film and the GaAs substrate. However, no increase in threading dislocation density has been observed in contrast to GaInNAs structures. It is therefore difficult to determine the effects, if any, of the film relaxation, but it is possible that higher-quality material could be grown if better lattice-matching were achieved. It is therefore concluded that multi-junction solar cells with greater than 40% efficiency can be constructed due to the high collection efficiency and resulting short-circuit current density of the devices having a layer with GaInNAsSb material.

### EXPERIMENTAL DETAILS

GaInNAs and GaInNAsSb double-heterostructure PIN diodes were grown at the Solid State Electronics Laboratory at Stanford University on a number of gallium arsenide (GaAs) substrates (where germanium could be used is an alternative substrate) using a load-locked Varian model Gen II solid-source MBE machine with nitrogen supplied by an SVT Associates Model 4.5 rf-plasma cell. One GaInNAs structure was grown without the use of deflection plates (hereafter referred to as “GaInNAs”), one GaInNAs structure was grown using deflection plates (hereafter referred to as “GaInNAs (DP)”), and a third structure incorporated a GaInNAsSb active layer, and was also grown using biased deflection plates (hereafter referred to as “GaInNAsSb”). The system and growth details in other contexts have been described in the technical literature at Bank et al., IEEE Journal of Quantum Devices, Vol. 40 p. 656 (2004). For the samples grown using the deflection plate bias, one plate was maintained at ˜40 V and one maintained at ground potential. A schematic cross section of a representative GaInNAsSb layer structure 10 is illustrated in FIG. 1A. As shown, the structure 10 includes a substrate 12, an n-type GaAs layer 14, an undoped GaInNAsSb active layer 16 of the type according to the invention that is slightly n-type, a p-type GaAs layer 18 and a cap of doped p+ GaAs 20. A buffer layer of doped n+ GaAs 22 is in place on the substrate 12 below the other layers, as explained below. The active layer (e.g., layer 16) of each sample was only unintentionally doped. The active GaInNAsSb material layer 16 is 1 μm thick and is composed of approximately 1-2% N, approximately 5-7% In and approximately 2-6% Sb. (For other samples grown without antimony, the structure is otherwise identical for the purpose of experimental comparison.) These compositions yielded material that was close to being lattice-matched to GaAs, as hereinafter explained. The wider band gap n and p barrier layers 18 and 22 of the double heterostructures are GaAs and have dopant densities equal to roughly 10¹⁸ cm⁻³. After growth, annealing was performed on the dilute nitride materials using a rapid thermal anneal with arsenic out-diffusion limited by a GaAs proximity cap. (The post-growth annealing temperature of the dilute nitride materials can be experimentally optimized for each sample by maximizing the peak photoluminescence (PL) intensity.)

Solar cell devices have been fabricated from these samples for purposes of testing and comparison. In a fully functional version, the front contacts may be constructed of gold (Au) and the back contacts may be annealed gold/tin/gold (Au/Sn/Au). Internal quantum efficiency spectra can be determined by dividing the external quantum efficiency by (I−R), where R is the measured specular reflectivity. To this end, light current-voltage photovoltaic measurements were performed using AM1.5 low-AOD solar conditions. The light intensity was adjusted to simulate the photocurrent density under a GaAs subcell in a monolithic multi-junction device, as determined by the device quantum efficiency and the AM1.5 low AOD solar spectrum. A GaAs optical filter was placed over the samples during L-I-V experiments to approximate the correct spectral content for the lower subcell in a monolithic multi-junction device.

### Device Results

The devices, including devices 100 according to the invention, were measured and analyzed by a national laboratory. FIG. 2 plots the internal quantum efficiency (IQE) 30 of representative devices from the GaInNAsSb solar cells according to the invention, as well as IQE 32 for GaInNAs solar cells and IQE 34 of GaInNAs (DP) solar cells. The absorption edges of the materials closely correspond to the band gaps as measured by Photoluminescence (PL): GaInNAs=1.08 eV; GaInNAs (DP)=1.03 eV; and GaInNAsSb=0.92 eV. The use of deflection plates increases the IQE 32 of the GaInNAs cell from 56% to 68% at maximum. The addition of antimony according to the invention drives the device IQE 30 even higher, reaching 79% at maximum. The GaInNAsSb material system 10 on substrate 12 (FIG. 1A) represents one of the smallest band gaps ever achieved (0.92 eV) in a dilute nitride solar cell with high carrier collection efficiency.

The GaInNAsSb subcell 10 can be expected to produce a short-circuit current density of 14.8 mA/cm², underneath a GaAs subcell 23 (FIG. 1B) in a multi-junction structure (as determined using the IQE and the low-AOD spectrum truncated at 880 nm to simulate the light-filtering effect of the overlying GaAs subcell). Under the same conditions, the GaInNAs (DP) devices have a substantially smaller short-circuit current density of 9.0 mA/cm². Reflection losses were not included in the calculation, although these losses can be expected to be less than a few percent with a high-quality antireflection coating. The larger photocurrent in the GaInNAsSb devices reflects both the increased photoresponse as well as the lower band gap. The current world record triple-junction device composed of lattice-matched GaInP/InGaAs/Ge has a short-circuit current density of 3.377 A/cm² at 236 suns, or 14.3 mA/cm² at 1 sun. This indicates that the narrow band gap GaInNAsSb cells have enough photoresponse to current match with the upper two sub-cells 23, 21 in a triple-junction solar cell 100 according to the invention.

The short-circuit depletion widths of each device, as determined from capacitance-voltage measurements, are, for the GaInNAs (DP), GaInNAs, and GaInNAsSb samples, 0.28, 0.37, and 0.44 μm, respectively. The GaInNAsSb subcell 10 made according to the invention has the widest depletion width, which explains the high collection efficiency. The GaInNAs (DP) device has a narrower depletion width than the GaInNAs device, and yet has higher collection efficiency. This is indicative of improved materials quality achieved using deflection plates, which yield long diffusion lengths enhancing carrier collection.

The device quantum efficiency spectra in FIG. 2 are also overlaid on the AM1.5 low-AOD solar spectrum 36, for comparison purposes. It is evident from this graph that the lower photocurrents of the GaInNAs and GaInNAs (DP) devices are partially the result of the lower fraction of solar irradiation available for absorption. The GaInNAs and GaInNAs (DP) devices absorb only a small fraction of the lobe of the solar spectrum between 0.92 and 1.1 eV, while the band gap of the GaInNAsSb material of subcell 10 allows that device to absorb the entire lobe. There is a strong atmospheric absorption band from about 0.85 to 0.92 eV. Since this region is bereft of solar radiation, a solar cell with a 0.85 eV band gap will not have significantly larger photocurrent than one with a 0.92 eV band gap.

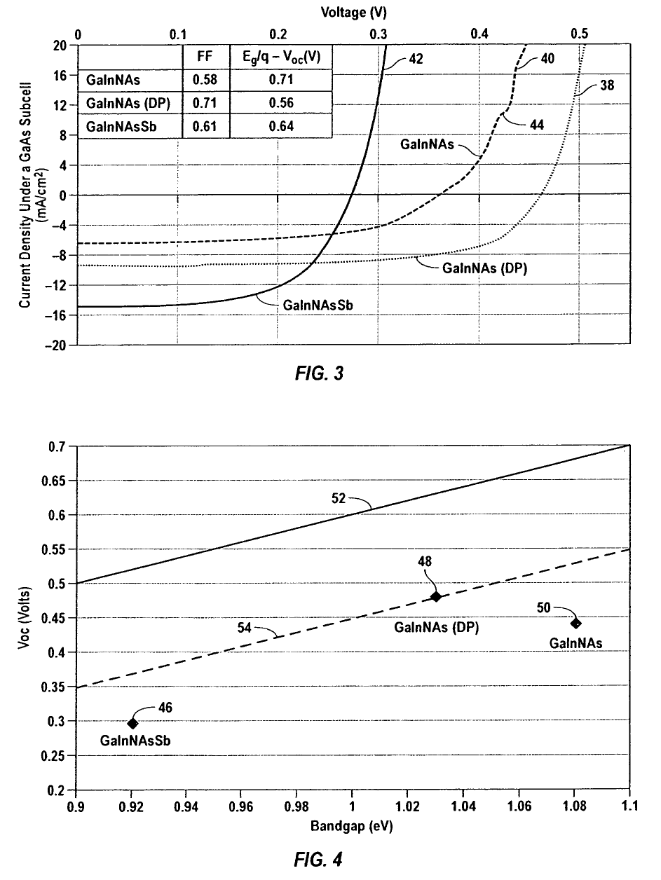

The current-voltage responses 38, 40 of the GaInNAs devices grown with and without deflection plates, and the response 42 of GaInNAsSb material of subcell 10 according to the invention, with the light intensity adjusted to simulate the photocurrent density under a GaAs subcell, are shown in FIG. 3. The improvement in solar cell performance suggests that the use of biased deflection plates in an MBE system during GaInNAs growth improved the material quality.

The GaInNAs (DP) cells displayed improved short-circuit current density, open-circuit voltage, fill factor, and band-gap-to-open-circuit voltage difference compared to the GaInNAs devices. However, the GaInNAs device photocurrent voltage curve has a kink 44 just above 0.4 V, which is likely due to a parasitic junction in the device. This nonideal nature of the GaInNAs devices makes them difficult to compare with the GaInNAs (DP) and GaInNAsSb-containing devices. The GaInNAsSb-containing devices 100 displayed higher short-circuit current densities than either of the GaInNAs devices. However, solar cell 100 according to the invention also showed the lowest open-circuit voltage, namely, 0.28 V. A typical Ge-containing device, however, has an open-circuit voltage of roughly 0.25 V at 1 sun. Since the GaInNAsSb-containing devices 100 produce sufficient current, this shows that using this material, rather than Ge, as the bottom junction in a triple-junction GaInP/GaAs/GaInNAsSb device has the potential to increase the power conversion efficiency of triple-junction cells 100 according to the invention by increasing the open-circuit voltage of the devices.

FIG. 4 is a plot that shows the open-circuit voltages 46, 48, 50 of the three types of devices with the light intensity adjusted to give a photocurrent of 20 mA/cm² in all of the devices. The solid line 52 indicates a band-gap-to-open-circuit voltage difference of 0.4 V, roughly the difference expected in a high-quality GaAs-based solar cell. All of the devices have a band-gap-to-open-circuit voltage difference larger than 0.4 V at this photocurrent value. Based merely on open-circuit voltage characteristics, one might be led to believe that the preferable device is the GaInNAs (DP) device, which has a band-gap-to-open-circuit voltage difference of 0.55 V. However, other factors are to be considered. The dotted line 54 shows a constant band gap to open-circuit voltage difference of 0.55 V (equal to that of the GaInNAs (DP) device), and it shows that the GaInNAs and GaInNAsSb band-gap-to-open-circuit voltage differences are larger than this value. The small band-gap-to-open-circuit voltage difference, along with the high carrier collection efficiency despite narrow depletion widths, merely indicates that the GaInNAs (DP) device has higher materials quality than the GaInNAsSb devices.

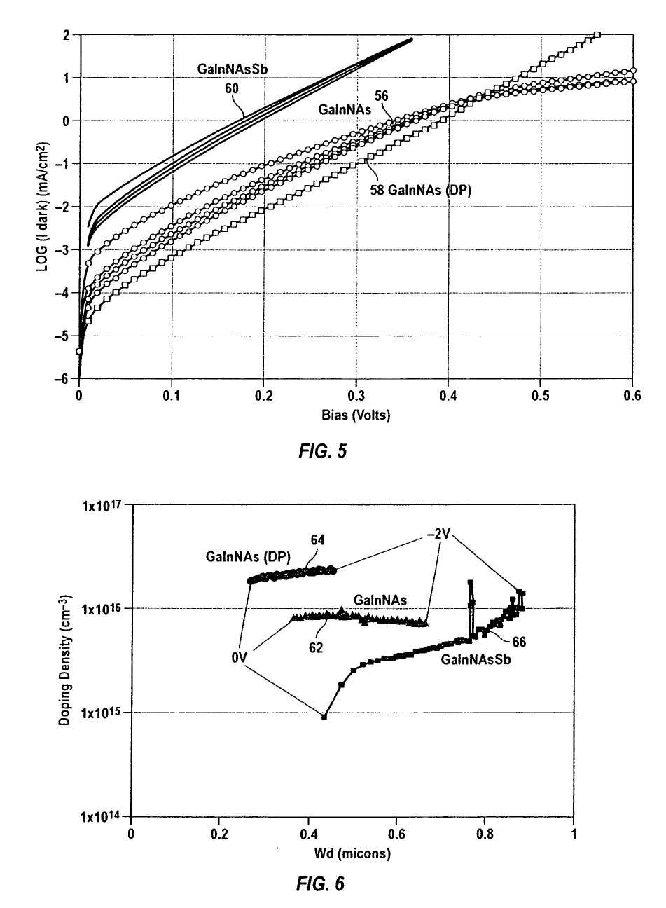

The dark current-voltage character can also provide insight into the materials quality and solar cell performance, and it is shown for each device in a semilog scale in FIG. 5. Several samples of each family of devices were compared. There is a wide variation in device dark current for four GaInNAs devices processed (traces 56), but the traces 58 of four GaInNAs (DP) devices and traces 60 of eight GaInNAsSb devices according to the invention are fairly consistent. The GaInNAs (DP) device samples, grown with deflection plate bias, have the lowest dark current. The GaInNAs devices, grown without deflection plate bias, have higher dark current, but the shape of the dark current voltage curves is also different. At voltages greater than the open-circuit voltage, the slope of the semilog dark current voltage curves changes. This is most likely the result of the parasitic junction present in the GaInNAs devices, and it makes comparisons with the dark current of the other devices somewhat difficult. The dark current in the GaInNAsSb device, however, is the largest, and is roughly two orders of magnitude larger than the GaInNAs (DP) device. Much of the increase in dark current can be attributed to the lower band gap of the antimonide material and is thus unavoidable. The additional increase in dark current for the GaInNAsSb devices (not accounted for by the lower band gap) could be due to a number of factors. The GaInNAsSb devices have wider depletion widths than the GaInNAs (DP) devices. Higher dark currents can be caused by increased Shockley-Read-Hall (SRH) recombination in the wider depletion regions. Higher defect concentrations, or defect species that are more effective recombination centers, could also cause increased dark current. Furthermore, ideal diode modeling indicates that most of the decrease in fill factor in the GaInNAsSb devices is explainable by the increased dark current. The remainder of the difference in fill factor may be due to increased field-aided collection in the GaInNAsSb device.

The slope of the semilog dark current voltage curve is related to the diode ideality. It is difficult to determine the exact n-factors for the GaInNAs and GaInNAsSb devices from the dark current voltage data since series resistance has caused nonlinearity in the semilog dark current-voltage curves for these devices. However, the n-factor for the GaInNAs (DP) devices is roughly 1.4. From analysis of roughly linear regions of the GaInNAs and GaInNAsSb devices, it seems that all three devices have ideality factors significantly larger than 1. Due to n-factors that are greater than unity, all of the devices in this study are predicted to display a larger increase in open-circuit voltage under concentrated sunlight than would be expected from ideal diodes having n=1. Thus, the aforementioned advantage of the GaInNAsSb subcell 10 over a Ge subcell in a multi-junction device could be more pronounced with concentration.

### Materials Parameters

The background doping is n-type for all of the dilute nitride films herein described. The background doping densities 62, 64, 66 as a function of the depletion width from capacitance-voltage measurements for representative devices of all three samples are shown in FIG. 6. The background doping density and short-circuit depletion width are inversely related for all of the samples; the lower the background doping density, the wider the short-circuit depletion width. The background doping density 66 of the GaInNAsSb film 16 is the lowest of the three samples, and it is significantly lower than the background doping density 64 in the GaInNAs (DP) material. It is speculated that the surfactant properties of antimony are directly responsible for the lower doping density by inhibiting the incorporation of impurities from the environment. As mentioned previously, the improved collection efficiency in the GaInNAsSb devices 100 is due, in large part, to the wider depletion width provided by the low background doping density. The change in doping density throughout the GaInNAsSb depletion region is thought to be a result of differences in Sb concentration. Secondary ion mass spectrometry (SIMS) data from GaInNAsSb material have shown an increase in Sb concentration toward the film surface. This would have the effect of reducing the n-type doping near the surface of the film.

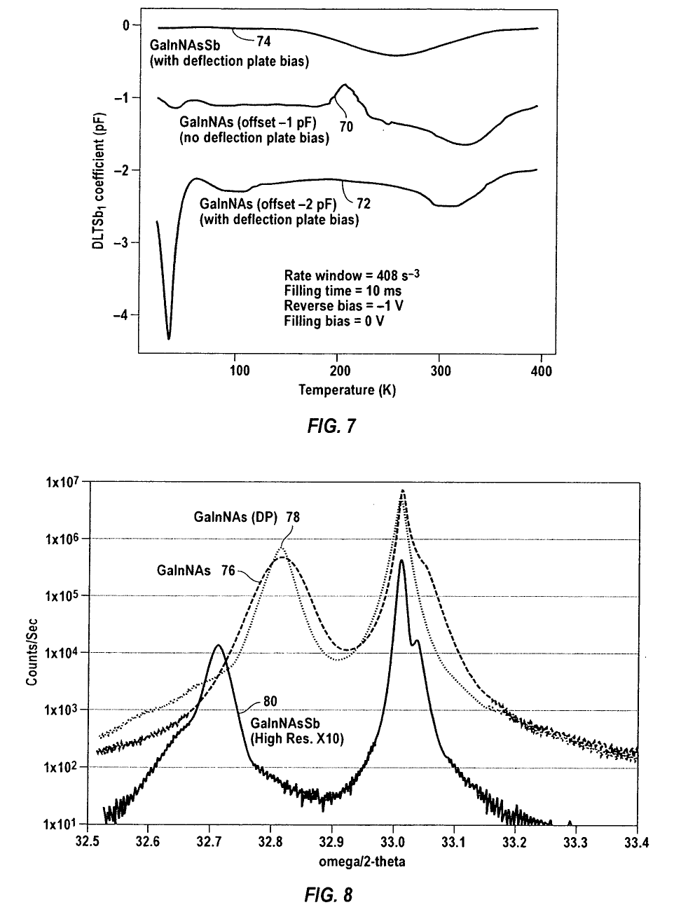

Fourier transform deep-level transient spectroscopy (DLTS) was performed using a FT-DLTS system with a cryostat temperature range from 30 to 400 K. FIG. 7 shows DLTS data 70, 72, 74 for the three p-i-n devices. These were measured with a rate window at 408/s, filling time of 10 ms, reverse bias of −1 Volt and filling bias of 0 Volt. This depiction shows just one Fourier component of the capacitance transients measured, but it does show that there are two electron traps and one hole trap in the GaInNAs material, three electron traps in the GaInNAs (DP) material, and one electron trap in the GaInNAsSb material.

Time-resolved PL measurements were performed on all three structures in order to determine the minority carrier lifetime in the dilute nitride films. The minority carrier lifetime of the GaInNAs film was 0.55 ns, and the use of deflection plates improved the lifetime of the GaInNAs (DP) film to 0.74 ns. This is consistent with the improved device properties observed. The GaInNAsSb had the shortest minority carrier lifetime, 0.20 ns. Despite having the shortest carrier lifetime, the GaInNAsSb films showed the highest collection efficiency. It therefore seems likely that the increase in collection efficiency of the GaInNAsSb devices is a result of the increased depletion width, which in turn is a result of the low background doping density in the antimonide film.

The lattice constants 76, 78, 80 of the dilute nitride films of respective devices are illustrated in FIG. 8. X-Ray Diffraction was performed in order to determine the lattice constants. Symmetric omega/2-theta rocking curves were done to investigate the out-of-plane (004) plane spacing, as illustrated in FIG. 8. The (004) plane spacing difference between the films and GaAs substrates is about 0.5% for both the GaInNAs and GaInNAs (DP) films. The GaInNAsSb films, however, show a roughly 0.8% (004) plane spacing difference between the film and the substrate. The symmetric rocking curves give no information, however, about the in-plane lattice constants of the film, and thus reciprocal space maps of both symmetric (004) and asymmetric (224) reflections were performed to determine the actual degree of lattice mismatch between the film and the substrate, and to determine if the films are coherently strained or relaxed. The results showed that the GaInNAs film is virtually coherent to the substrate, but the test of GaInNAsSb showed significant relaxation. From analysis of the symmetric and asymmetric reciprocal space maps it has been determined that the GaInNAsSb film is about 34% relaxed, while the GaInNAs film is only about 3% relaxed. The bulk mismatch, the mismatch between the unstrained cubic lattice constant of GaInNAsSb film and the GaAs substrate, is 0.50%, while it is only 0.21% for the GaInNAs film. It is assumed that the cubic anisotropic elastic constants of the dilute nitride films are equal to those of InGaAs with similar indium compositions as in the dilute nitride films, that all stresses are biaxial, and that the tilt is zero.

Surprisingly, the III-V GaInNAsSb films 10 made in accordance with the invention were significantly more relaxed than either of the GaInNAs films, and yet they showed the highest collection efficiency. Other device characteristics of the antimonide solar cells, however, such as open-circuit voltage, were somewhat degraded compared to the GaInNAs (DP) devices. It is possible that, if better lattice-matching between film and substrate were achieved, then some improvement in materials properties and device characteristics could result. On the other hand, the relaxation in the antimonide film does not seem to have created any additional threading dislocations, as measured by CL imaging. The threading dislocation density (TDD) in all of the structures was relatively low, and there was not much difference detected between the different structures. The GaInNAs film had a TDD of roughly 1×10⁵ cm⁻², the GaInNAs (DP) film was 1×10⁵ cm⁻² to 5×10⁵ cm⁻², and the GaInNAsSb had a slightly lower TDD, below 1×10⁵ cm⁻² (which is the lower resolution limit of the technique). Finally, however, it is noted that antimony is known to vastly improve the properties of highly strained narrow band gap dilute nitride quantum wells in laser structures, and it is possible that completely lattice-matched unstrained dilute nitride material might not show the same benefits from the incorporation of antimony.

The invention has now been explained with reference to specific embodiments. Other embodiments will be evident to those of skill in the art. Therefore it is not intended that this invention be limited, except as indicated by the appended claims.

What is claimed is:

1. A solar cell comprising:
a substrate suitable for growing III-V materials; and
a triple junction of layers of III-V materials upon said substrate;
one of the layers being a dilute nitride comprising an alloy of gallium, indium, nitrogen, arsenic and an effective amount of antimony grown by molecular beam epitaxy;
such that each junction has a different bandgap while said layers are matched in a substantially unstrained lattice to said substrate and to one another to promote solar energy conversion over the range of bandgaps.

2. The solar cell according to claim 1 wherein one of said layers is an alloy of gallium, indium and phosphorous.

3. The solar cell according to claim 2 wherein said gallium, indium, phosphorous layer includes aluminum.

4. The solar cell of claim 2 wherein one of said layers is an alloy of gallium and arsenide.

5. The solar cell according to claim 1 wherein said substrate is gallium arsenide.

6. The solar cell according to claim 1 wherein said substrate is germanium.

7. The solar cell according to claim 1 wherein the dilute nitride layer comprises 1-2% nitrogen, 5-7% indium, and 2-6% antimony to yield a lattice structure that is substantially lattice matched to a gallium arsenide lattice structure.

8. The solar cell according to claim 7 wherein said dilute nitride layer is substantially 1 micron in thickness.

9. A method for making a solar cell comprising:
providing a substrate suitable for growing III-V materials; and
growing a triple junction of layers of III-V materials upon said substrate;
one of the layers being a dilute nitride comprising an alloy of gallium, indium, nitrogen, arsenic and an effective amount of antimony grown by molecular beam epitaxy;
such that each junction has a different bandgap while said layers are matched in a substantially unstrained lattice to said substrate and to one another to promote solar energy conversion over the range of bandgaps.

10. The method according to claim 9 wherein one of said layers is an alloy of gallium, indium and phosphorous.

11. The method according to claim 10 wherein said gallium, indium, phosphorous layer includes aluminum.

12. The method according to claim 10 wherein one of said layers is an alloy of gallium and arsenide.

13. The method according to claim 9 wherein said substrate is gallium arsenide.

14. The method according to claim 9 wherein said substrate is germanium.

15. The method according to claim 9 wherein the dilute nitride layer comprises 1-2% nitrogen, 5-7% indium, and 2-6% antimony to yield a lattice structure that is substantially lattice matched to a gallium arsenide lattice structure.

16. The method according to claim 15 wherein said dilute nitride layer is substantially 1 micron in thickness.
